(19) United States
(12) Patent Application Publication
(10) Pub. No.: US 2026/0123550 A1
(43) Pub. Date: Apr. 30, 2026

(54) SUBSTRATE BONDING SYSTEMS AND RELATED METHODS

(71) Applicant: SEMICONDUCTOR COMPONENTS INDUSTRIES, LLC, Scottsdale, AZ (US)

(72) Inventors: JeongHyuk PARK, Incheon (KR); Gyuwan HAN, Incheon (KR); Keunhyuk LEE, Suzhou (CN)

(73) Assignee: SEMICONDUCTOR COMPONENTS INDUSTRIES, LLC, Scottsdale, AZ (US)

(21) Appl. No.: 18/925,452

(22) Filed: Oct. 24, 2024

(51) Int. Cl. H01L 23/498; H01L 23/00; H01L 25/065

(52) U.S. Cl. CPC H10W 90/701; H10W 70/65; H10W 70/685; H10W 90/00; H10W 72/07554; H10W 72/5449; H10W 72/547; H10W 90/755

(57) ABSTRACT

Implementations of a semiconductor package may include a metal containing substrate including a solder preform coupled thereto and a laminated substrate including an opening. The laminated substrate may be fixedly coupled to the metal containing substrate through the solder preform.

### BACKGROUND

### 1. Technical Field

Aspects of this document relate generally to semiconductor packages, such as packages for semiconductor die.

### 2. Background

Various semiconductor packages have been devised that provide mechanical support for a semiconductor die attached thereto. Semiconductor packages can also assist with making electrical connections between a semiconductor die and a circuit board or motherboard to which the semiconductor package is attached. Various semiconductor packages can also provide protection from shock or vibration.

### SUMMARY

Implementations of a semiconductor package may include a metal containing substrate including a solder preform coupled thereto and a laminated substrate including an opening. The laminated substrate may be fixedly coupled to the metal containing substrate through the solder preform.

Implementations of a semiconductor package may include one, all, or any of the following:

The solder preform may extend out of the opening.

The solder preform may be contained within the opening.

The solder preform may form an electrical connection with only one electrically conductive layer included in the laminated substrate.

The solder preform may forms an electrical connection with at least two electrically conductive layers included in the laminated substrate.

The solder preform may be melted to effect the fixed coupling of the laminated substrate to the metal containing substrate.

Implementations of a semiconductor package may include a metal containing substrate including a metal projection and a laminated substrate including an opening. The laminated substrate may be fixedly coupled to the metal containing substrate through an adhesive fixedly coupled between the metal projection extending through the opening and the laminated substrate.

Implementations of a semiconductor package may include one, all, or any of the following:

The metal projection may be a pin and the metal containing substrate may include a pin opening through which the pin extends.

The pin may be held in the pin opening using an adhesive.

The pin may be held in the pin opening using a jig.

The metal projection may be a portion of the metal containing substrate itself.

The metal projection may be a portion of the metal containing substrate that may be bent upwardly substantially 90 degrees.

The adhesive may be cured using a laser beam.

Implementations of a semiconductor package may include a metal containing substrate including a horizontal section, the horizontal section including a first opening therein and a second opening thereon, the first opening and the second opening connected by a flow channel; and a laminated substrate including a first largest planar surface. The laminated substrate may be fixedly coupled to the metal containing substrate at the first largest planar surface through an adhesive included in the second opening and in the flow channel.

Implementations of a semiconductor package may include one, all, or any of the following:

The base of the first opening may be at a first distance into a thickness of the horizontal section and a base of the second opening may be at a second distance into the thickness of the horizontal section.

The first distance may be smaller than the second distance.

The flow channel may permit gravity flow of the adhesive when melted by a laser beam from the first opening into the second opening.

The flow channel may be exposed on a same side of the horizontal section that may include the first opening and the second opening.

The flow channel may be narrower than a width of the first opening and narrower than a width of the second opening.

The flow channel may be the same width as a width of the first opening and a width of the second opening.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is an exploded view of an implementation of a semiconductor package;

FIG. 2 is a side view of an implementation of a semiconductor package;

FIG. 3 is a side view of the semiconductor package implementation of FIG. 2 with solder preforms coupled thereto;

FIG. 4 is a side view of the semiconductor package implementation of FIG. 3 with a laminated substrate being coupled thereto;

FIG. 5 is a side view of the semiconductor package implementation of FIG. 4 during melting to the solder preforms using laser beams;

FIG. 6 is a side view of the semiconductor package implementation of FIG. 5 following coupling of the laminated substrate using the solder preforms;

FIG. 7 is a perspective cross sectional view of a laminated substrate with a solder preform inserted into an opening therein showing formation of an electrical connection with only one electrically conductive layer of the laminated substrate;

FIG. 8 is a perspective cross sectional view of a laminated substrate with a solder preform inserted into an opening therein showing formation of an electrical connection with two electrically conductive layers of the laminated substrate;

FIG. 9 is a side view of a semiconductor package implementation;

FIG. 10 is a side view of the semiconductor package implementation with openings formed therein;

FIG. 11 is a side view of the semiconductor package implementation of FIG. 10 with pins inserted into the openings;

FIG. 12 is a side view of the semiconductor package implementation of FIG. 11 during curing of an adhesive using a laser beam;

FIG. 13 is a side view of another implementation of a semiconductor package showing projections extending therefrom;

FIG. 14 is a detail perspective view of a projection of the semiconductor package of FIG. 13;

FIG. 15 is a side view of the semiconductor package of FIG. 13 with a laminated substrate oriented above it prior to bonding;

FIG. 16 is a side view of the semiconductor package of FIG. 15 during curing of an adhesive using a laser beam;

FIG. 17 is a side view of an implementation of a semiconductor package;

FIG. 18 is a side view of another implementation of a semiconductor package;

FIG. 19 is a side view of the semiconductor package implementation of FIG. 18 with a laminated substrate oriented above it prior to bonding; and

FIG. 20 is a perspective detail view of the channel structure of the semiconductor package implementation of FIG. 18 during an adhesive curing operation.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages and related methods, and implementing components and methods, consistent with the intended operation and methods.

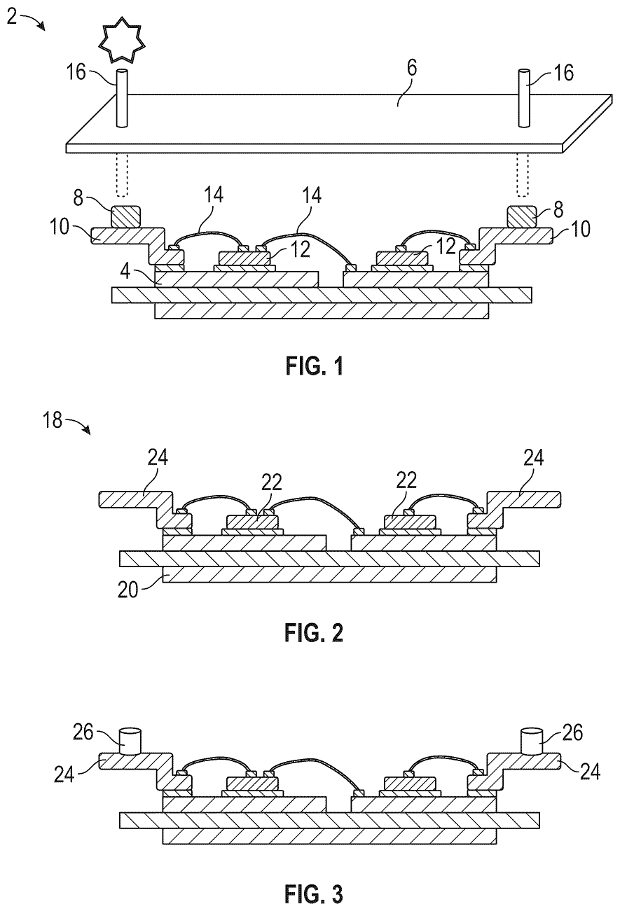

Referring to FIG. 1, an implementation of a semiconductor package 2 in an exploded view during an adhesive curing operation is illustrated. As illustrated, the semiconductor package includes a metal containing substrate 4 and a laminated substrate 6 that are intended to be coupled together using adhesive 8 that is applied to the leads 10 of the metal containing substrate 4. In this implementation, the metal containing substrate is a direct bonded copper substrate, but the metal containing substrate may be any other substrate type that contains electrically conductive traces thereon including, by non-limiting example, brazed substrates, leadframes, single sided substrates, dual side substrates, insulated metal substrates or any other substrate type that includes a metal conducting structure that can be used for bonding with another laminated substrate. The metal containing substrate may contain one or more electrically conducting layers, one or more non-electrically conducting layers, and any combination of the foregoing. The one or more conducting layers may be patterned to form various traces and other electrically conductive areas on the substrate. In some implementations, the metal-containing substrate may include multiple electrically conductive layers and multiple electrically non-conductive layers. In such implementations, some layers can be patterned to form electrical circuits and may include electrically conductive blind vias and/or through vias. A wide variety of substrate configurations are possible in the various semiconductor package implementations disclosed herein using the principles disclosed herein.

The laminated substrate 6 can be any of a wide variety of laminated substrate materials including, by non-limiting example, a printed circuit board (PCB), FR4, FR6, a multi-layer printed circuit board, or any other substrate type formed using a lamination buildup process. While in the semiconductor package implementation 2 illustrated in FIG. 1 semiconductor die 12 are illustrated as being bonded to the metal containing substrate 4, in various other implementations, one or more semiconductor die may also be coupled to the laminated substrate as well. Any of a wide variety of semiconductor substrate types may be employed for the semiconductor die packaged using the semiconductor package designs disclosed in this document including, by non-limiting example, silicon, silicon carbide, gallium arsenide, gallium nitride, silicon on insulator, ruby, sapphire, or any other semiconductor material type. The type of semiconductor die included in the semiconductor package implementations disclosed herein may be any of a wide variety of types including, by non-limiting example, power semiconductor die, diodes, metal oxide field effect transistors (MOSFETs), insulated gate bipolar junction transistors (IGBTs), hybrid devices, rectifiers, random access memory, high-electron-mobility transistors, image sensors, wide bandgap semiconductor devices, hybrid devices, or any other semiconductor die/device type. The semiconductor die may be thinned die in various implementations and may be thinned using, by-non-limiting example, wafer backside grinding (WBG), thinning, lapping, polishing, or other techniques used to reduce the thickness or create a semiconductor substrate a desired thickness.

The semiconductor die can be attached to the metal-containing substrate or the laminated substrate using any of a wide variety of die attach systems and methods including, by non-limiting example, die attach film, sintering, solder, gluing, molding, or otherwise forming a bond between the semiconductor die and the substrate. The particular system for forming the bond is determined by considering the material type(s) of the semiconductor die and the material type(s) of the metal-containing substrate or laminated substrate. In either of the metal containing substrate or the laminated substrate, one or more semiconductor die may be embedded in one or more layers or between one or more layers of the substrates. Various clips, wires, and other electrical connector types may be included and used to connect the semiconductor die and/or substrates to components of the package or to a circuit board or motherboard to which the package is attached. Either or both of the metal containing substrate and the laminated substrate may include electrically conducting layers and/or non-electrically conducting layers in various implementations.

The ultimate semiconductor package that includes the metal containing substrate and the laminated substrate may be cooled using various techniques including, by non-limiting example, top side cooling, bottom side cooling, or dual side cooling. The ultimate semiconductor package may be a power module that includes various semiconductor power die and related power conversion equipment. In some implementations, the semiconductor package may be an inverter. In various implementations a mold compound may be formed partially or entirely around the metal containing substrate and the laminated substrate but in others no mold compound may be used. A potting compound could also be used in combination with one or more housings to provide protection from moisture to either or both of the metal containing substrate and the laminated substrate. In some implementations, whether a mold compound or potting compound are employed, a first electrically conducting layer in either or both of the laminated substrate and the metal containing substrate may be exposed and not covered with mold or potting compound. The mold compound may be non-electrically conductive and made of a non-electrically conductive material in the form of a layer or molded shape.

In FIG. 1, the use of leads/electrical connectors 10 is illustrated to help form electrical connections and/or provide a mechanical coupling mechanism that allows for attachment of the laminated substrate 6 to the metal-containing substrate while providing sufficient standoff to keep the laminated substrate 6 from contacting the semiconductor die and/or electrical connectors (in this case bond wires 14). However, the use of leads to provide a mechanical standoff may not be used in various semiconductor package implementations that employ the principles disclosed herein but the mechanical standoff may be accomplished using other mechanical features/structures as further discussed herein. The leads/electrical connectors may be composed of any of a wide variety of materials, including, by non-limiting example, gold, silver, aluminum, alloys of gold, alloys of silver, alloys of aluminum, any combination thereof, or any other electrically conductive material. In such implementations, the adhesive 8 may be applied directly to the surface of the metal-containing substrate 4 itself and used to bond the laminated substrate 6 thereto.

In various semiconductor package implementations, if the adhesive 8 is thermally cured, the use of ovens or other heated enclosures can be used to finish forming a fixed bond between the laminated substrate 6 and the metal containing substrate 4. While this can be convenient and may work where the thermal bonding of other components to either or both the laminated substrate and the metal containing substrate is also being effected at the same time, in other semiconductor package implementations and other implementations of methods of making a semiconductor package, heating the entire assembly may not be an option. In such situations, a focused heating of the adhesive material can be done using a laser beam. However, as illustrated in FIG. 1, where the laminated substrate 6 is in between the laser beam 16 and the adhesive 8, the material of the laminated substrate will absorb a substantial amount of the light of the laser beam 16, preventing sufficient heat from reaching the adhesive 8 to complete the curing operation. Also, the laser beam 16 may damage one or more of the layers of the laminated substrate 6 due to excessive heating caused by light absorption from the beam 16.

Referring to FIG. 2, another implementation of a semiconductor package 18 is illustrated that includes a metal containing substrate 20 with semiconductor die 22 thereon similar to that illustrated in FIG. 1 which may be any metal containing substrate or semiconductor die type disclosed in this document. Here the use of leads/electrical connectors 24 is also illustrated to provide electrical connections from the package and a mechanical standoff for a laminated substrate, similar to the design of the semiconductor package 2 of FIG. 1.

Referring to FIG. 3, the semiconductor package 18 is illustrated following coupling of solder preforms 26 along the leads 24. In various implementations, the solder preforms 26 may be placed in an opening in the leads 24 that is designed to receive an end structure of the solder preforms. In others, the solder preforms 26 may be coupled using an adhesive to the leads 24. In yet others, the solder preforms may be partially soldered or fully soldered to the leads 24 using a heating process. A wide variety of methods of coupling the solder preforms 26 with the leads 24 may be employed in various implementations.

While the shape of the solder preforms 26 illustrated in FIG. 3 is that of a cylindrical prism, wide variety of other shapes may be employed including, by non-limiting example, a square prism, a triangular prism, an elliptical prism, a cone, a truncated cone, a rectangular prism, a pyramid, a truncated pyramid, a rod, or any other three dimensional shape capable of being engaged into a hole. The material of the solder preforms 26 may be any solder material or solder alloy that is capable of being formed into a three dimensional shape with sufficient mechanical rigidity.

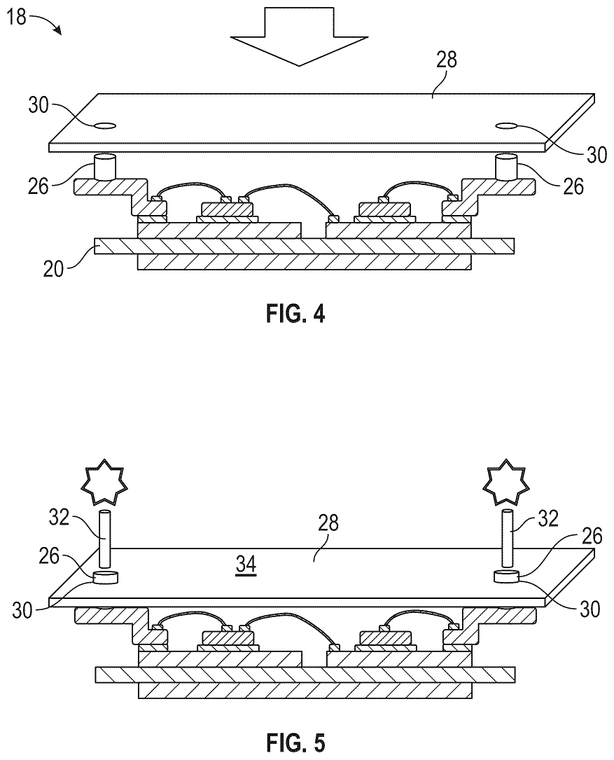

Referring to FIG. 4, the semiconductor package 18 is illustrated with a laminated substate 28 oriented above it which contains openings 30 therein that are dimensioned to receive an end of the solder preforms 26. The shape of the ends of the solder preforms 26 may correspond with a shape of the openings 30 to allow the laminated substrate 28 to rest in a desired position during a solder preform melting operation to achieve a desired relative position between the laminated substrate 28 and the metal containing substrate 20. The shape of the openings 30 may be, by non-limiting example, a circle, an ellipsoid, triangular, square, rectangular, star-shaped, hexagonal, octagonal, or any other closed shape.

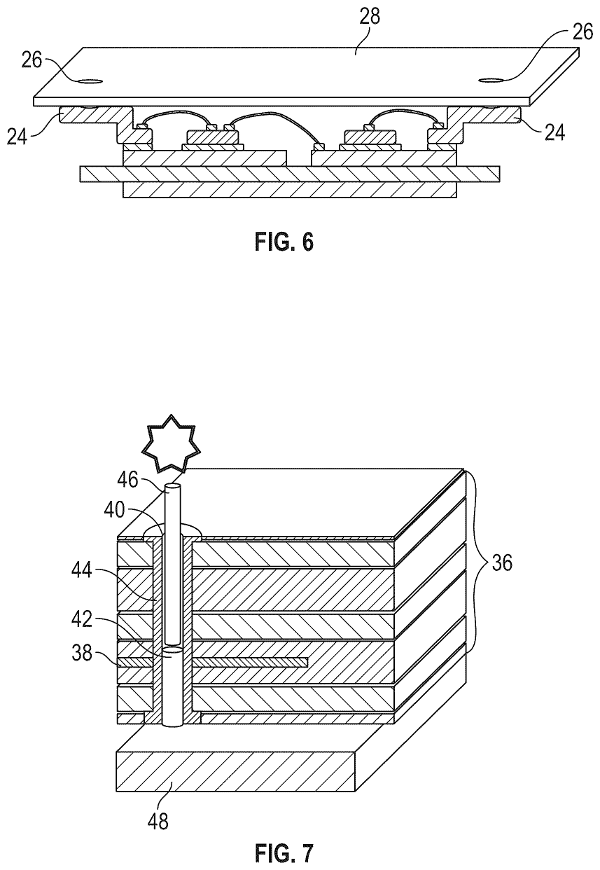

FIG. 5 illustrates the semiconductor package 18 during a solder preform melting operation where laser beams 32 are applied to the exposed ends of the solder preforms 26. While the ends of the solder preforms 26 are illustrated as extending out of the openings 30 in the implementation illustrated in FIG. 5, in others, the ends of the solder preforms 26 may not extend into the openings 30 above a largest planar surface 34 of the laminated substrate 28. In such implementations, following the melting operation using the laser beams 32, the ends of the solder preforms 26 remain contained within the opening. FIG. 6 illustrates the ends of the solder preforms 26 following the melting operation which indicates that a mechanical bond between the laminated substrate 28 and the leads 24 has been formed.

In addition to using to form a mechanical bond between the laminated substrate 28 and the metal containing substrate 20, the solder preforms 26 along with the laser melting process can allow for formation of various electrical connections to one or more electrically conductive layers in the laminated substrate. Referring to FIG. 7, a detail view of a laminated substrate 36 that includes various layers is illustrated. Also illustrated herein is an electrically conductive layer 38 included as one of the various layers of the laminated substrate 36. Opening 40 is illustrated following receipt of solder preform 42 therein. The solder preform 42 illustrated here has a length that is shorter than the thickness of the laminated substrate 36 allowing it to rest at the bottom of the opening 40 under gravity force. The length of the solder preform 42 is long enough to reach the location of the electrically conductive layer 38 in the stack of layers that form the laminated substrate 36.

The opening 40 in this implementation has been laser drilled through the various layers and then plated to form an electrically conductive layer/via 44. Laser beam 46 is illustrated in use during a melting operation of the solder preform 42 which will result in formation of an electrical connection between the material of lead 48, the via 44, and the electrically conductive layer 38. Because the length of the solder preform 42 is short enough, it forms an electrical connection only with the electrically conductive layer 38. While the use of laser drilled and plated openings is illustrated in FIG. 7, in other implementations, the openings may be formed using other techniques, including, by non-limiting example, drilling, etching, punching, or other methods of forming a hole in the material(s) of the laminated substrate. Also, the opening 40 may not be plated with an electrically conductive layer, and so only the original exposed materials of the various layers making up the laminated substrate 36 remain exposed. In such implementations, the length of the solder preform 42 may ultimately determine whether just one, two, or more electrically conductive layers of the laminated substrate 36 are electrically coupled with the lead 48.

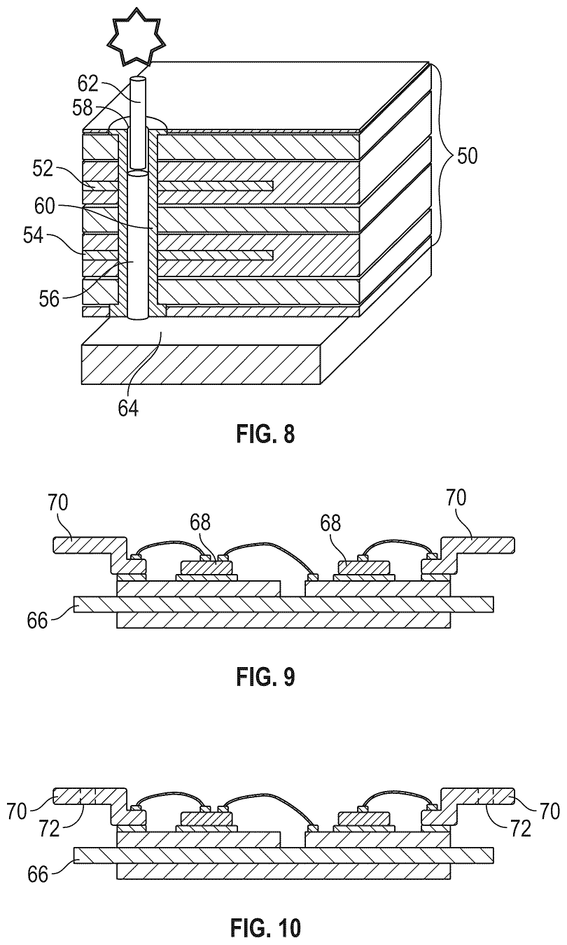

Referring to FIG. 8, another implementation of a laminated substrate 50 that includes various layers is illustrated. In this implementation, two electrically conductive layers 52, 54 are included in the laminated substrate 50. Solder preform 56 has been inserted into opening 58 in the laminated substrate 50 that includes an electrically conductive layer/via 60. FIG. 8 shows laser beam 62 applied to the solder preform 56 during a melting operation which, when completed, will form an electrical connection between lead 64, electrically conductive layer/via 60 and both of the electrically conductive layers 52, 54. In this way, while the thickness of the laminated substrate 50 remains the same, the use of solder preforms with different thicknesses can be used during assembly of the package to create desired electrical connections between one or more electrically conductive layers in the laminated substate 50 and the lead 64.

Other structures can be used to form a bond between a laminated substrate and a metal containing substrate. Referring to FIG. 9, an implementation of a metal containing substrate 66 is illustrated that includes semiconductor die 68 like any disclosed herein. This metal containing substrate implementation 66 includes leads 70 like those disclosed herein. However, as previously discussed, the use of leads 70 may not be utilized in various implementations, and the various implementations disclosed herein may be carried out through directly modifying the material of the metal containing substrate 66 itself.

FIG. 10 illustrates the metal containing substrate 66 following formation of openings 72 through the material of the leads 70. These openings 72 are shown in this side view as being in dotted lines to indicate that the openings 72 do not extend completely through the length of the leads into the paper but are simply formed through the material of the leads 70. The openings 72 may be formed through the material of the leads 70 (or the material of the metal containing substrate itself in various implementations) using any of a wide variety of techniques, including, by non-limiting example, drilling, laser drilling, etching, punching, casting, milling, or any other technique for forming an opening through the material of the lead/metal containing substrate.

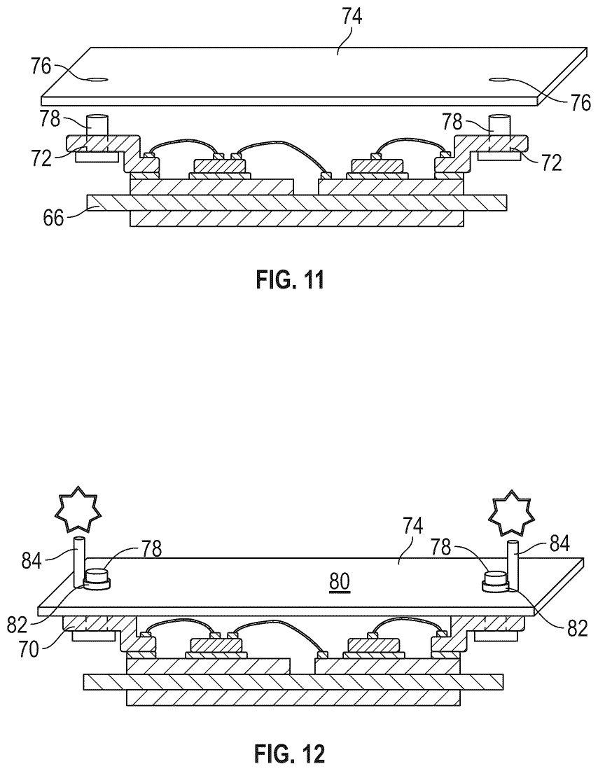

Referring to FIG. 11, a laminated substrate 74 with openings 76 therethrough is illustrated oriented above metal projections 78. In this implementation, the metal projections 78 are pins that have been inserted into the openings 72 and which are aligned with the openings 76. The shape of the pins 78 and the openings 72 is designed to correspond to allow the laminated substrate 74 to be held mechanically in place during subsequent bonding operations. In the implementation illustrated in FIG. 11, the pins 78 are held in place using an adhesive to prevent them from dropping out of the openings 72 under gravity force. However, in other implementations, a jig or fixture may be used to hold the pins 78 or the pins 78 and the metal containing substrate 66 in the desired orientation as the laminated substrate 74 is placed over the pins and subsequent processing occurs. In yet other implementations, the laminated substrate 74 may be placed over the leads 70 with its openings 76 aligned with the corresponding openings 72 in the leads 70. The pins 78 may then be dropped into or pressed into the openings 76 and openings 72. If the pins 78 have a “foot” or other flange shape that is wider than a width of the pins, then the foot works to hold the pins 78 in place without the need for a jig to hold them in place. A wide variety of shapes of the pins 78 may be utilized in various implementations including, by non-limiting example, a square prism, a triangular prism, an elliptical prism, a cone, a truncated cone, a rectangular prism, a pyramid, a truncated pyramid, a rod, or any other three dimensional shape capable of being engaged into a hole.

Referring to FIG. 12, following placement of the laminated substrate 74 onto the pins 78, the ends of the pins 78 are illustrated as extending above the largest planar surface 80 of the laminated substrate 74. Here adhesive 82 has been applied around the pins 78 and is currently being cured using laser beams 84. In some implementations where the ends of the pins 78 do not extend above the largest planar surface 80, the adhesive 82 may completely cover the ends of the pins 78. In yet other implementations where the pins include a foot, the adhesive 82 may be applied either before or after the pins have been inserted into the openings 72, 76 and the foot may contact the adhesive. The adhesive may be any thermally curable adhesive type disclosed herein which may include, by non-limiting example, an epoxy, a resin, a polymer, a filler, a silicone, any combination thereof, or any other adhesive type capable of forming a bond between the material of the pins 78, the leads 70, and the laminated substrate 74.

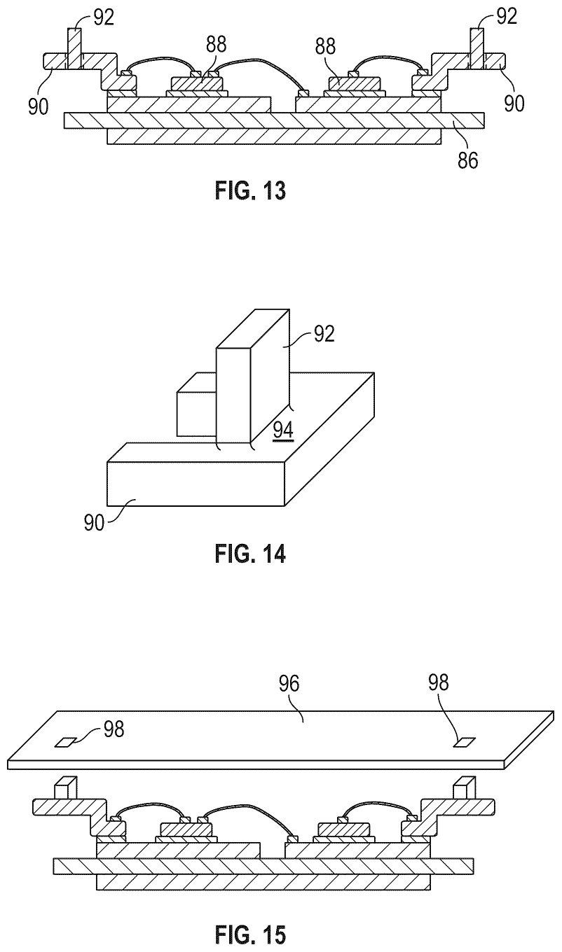

While in the semiconductor package implementation of FIGS. 9-12 the metal projection is in the form of a pin, in other implementations, the metal projection may be formed as a portion/integral portion of the lead or metal/containing substrate itself. Referring to FIG. 13, an implementation of a metal containing substrate 86 is illustrated that includes semiconductor die 88 like any disclosed herein and leads 90. As illustrated, in FIG. 13, the leads 90 each include metal projections 92 that are formed from portions of the leads 90 that are bent/raised upwardly from the leads 90. FIG. 14 illustrates a detail perspective view of one of the leads 90 that shows the projections 92 that extends upwardly from a plane 94 of the lead 90 substantially at a 90 degree angle. In other implementations, however, the angle could be more or less than 90 degrees. In this implementation, a rectangular portion of the lead 90 has been bent upwardly after being punched from the plane 94 into a substantially perpendicular position. While the resulting metal projection 92 is in the form of a rectangular prism, in other implementations other shapes may be used including, by non-limiting example, a square prism, a rounded prism, an elliptical prism, or other shapes. The metal projection may be formed using any of a wide variety of methods to achieve the desired shape, including, by non-limiting example, punching and bending; punching, bending, and shaping; casting; cutting and bending; milling and bending; or any other forming technique that can be utilized to create the desired shape of the projections.

While in the foregoing discussion the formation of the metal projections from the material of the leads 90 has been discussed, the same principles can apply if the metal projections 92 are formed from the material of the metal containing substrate 86. In such implementations, additional variations including the use of pins as metal projections that are attached/bonded/soldered/welded to the metal containing substrate 86 where the pins contain a stop structure to prevent the laminated substrate from dropping all the way down the length of the pins could also be employed. A wide variety of various metal projection types involving the material of the metal containing substrate or components attached thereto may be constructed using the principles disclosed herein.

Referring to FIG. 15, a laminated substrate 96 is illustrated in position prior to being placed over metal projections 92 at corresponding openings 98. The shape of the openings 98 corresponds with the shape of the particular metal projections to allow the laminated substrate 96 to be mechanically supported during subsequent bonding operations. The openings may be formed using any of the methods disclosed herein that are capable of removing the material of the laminated substrate 96 including, by non-limiting example, etching, punching, laser drilling, milling, drilling or any other removal technique.

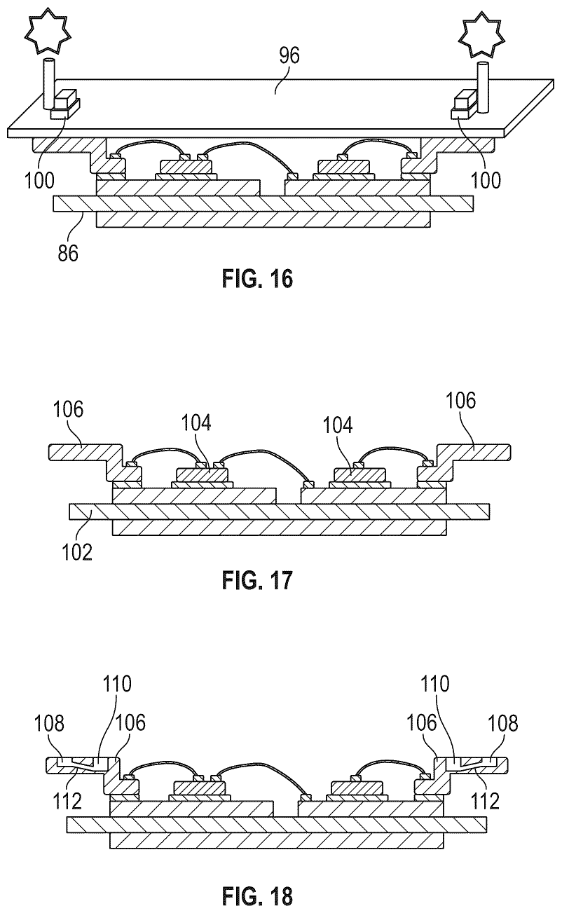

FIG. 16 shows the metal containing substrate 86 and laminated substrate 96 during an adhesive curing operation where adhesive 100 has been applied around the metal projections 92. Laser beams are illustrated during the thermal curing operation of the adhesive 100 which forms a fixed bond between the laminated substrate 96 and the metal projections 92. The adhesive 100 employed in this implementation may be any thermally curable adhesive type disclosed in this document.

Various other semiconductor package implementations disclosed here do not use openings in the laminated substrate when forming the adhesive bond with the metal containing substrate. Referring to FIG. 17, an implementation of a metal containing substrate 102 is illustrated that includes semiconductor die 104 thereon which may be any type disclosed in this document. The metal containing substrate 102 also includes leads 106 similar to those disclosed in the other implementations in this document. However, the structures and methods of formation disclosed herein could also be applied to the material of the metal containing substrate 102.

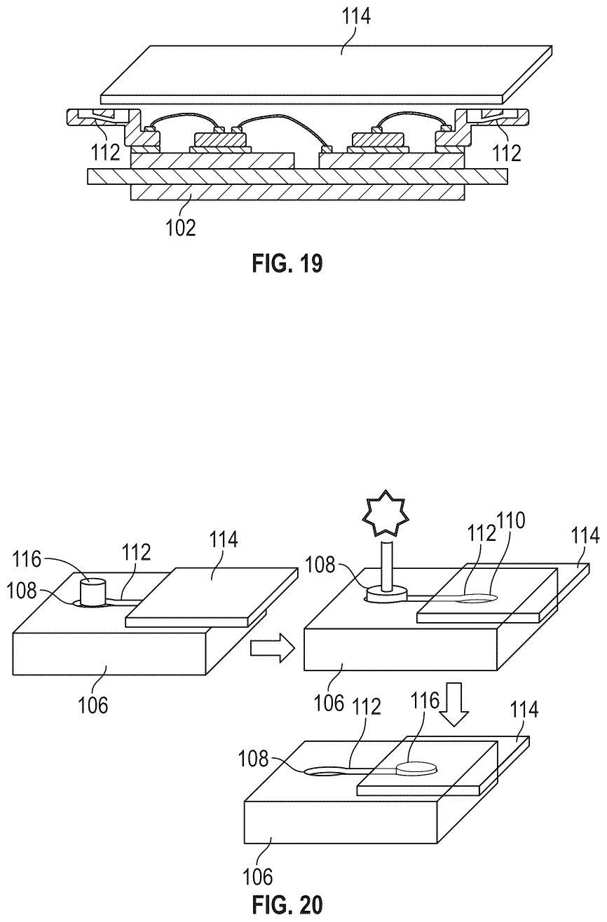

FIG. 18 illustrates a side cross sectional view of the leads 106 showing the formation of two openings therein, a first opening 108 and a second opening 110 that are now joined by a channel 112. The structure of the first opening 108 and second opening 110 along with the channel may be formed using various techniques, including, by non-limiting example, milling, casting, drilling, or etching. FIG. 19 illustrates the metal containing substrate 102 with a laminated substrate positioned above it prior to bonding using an adhesive.

Referring to FIG. 20, a detail view of the first opening 108, channel 112, and second opening 110 are illustrated during an adhesive bonding operation. As illustrated, an edge of the laminated substrate 114 is aligned over the second opening 110 and a plug or other three dimensionally shaped portion of adhesive 116 is placed in the first opening 108. A laser beam 118 is then directed at the adhesive 116, which causes it to melt and flow under gravity force and/or surface tension force down the channel 112 into the second opening 110. As illustrated, the channel 112 directs the flowing adhesive 116 under the edge of the laminated substrate 114 causing the adhesive to pool in the second opening 110 until it contacts the surface of the laminated substrate 114. As illustrated in the third graphic in FIG. 20, the resulting pooled adhesive 116 then cools, forming a bond with the laminated substrate 114 and the material of the lead 106 in the second opening 110. In this way, the adhesive bond is formed to fixedly couple the laminated substrate 114 with the metal containing substrate 102.

As previously discussed, this same technique could be applied by forming the first and second openings and the channel in the material of the metal containing substrate itself. In some implementations, standoffs could be applied to the bottom surface of the laminated substrate 114 for contacting with the melted adhesive.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a metal containing substrate comprising a solder preform coupled thereto; and
a laminated substrate comprising an opening;
wherein the laminated substrate is fixedly coupled to the metal containing substrate through the solder preform.

2. The package of claim 1, wherein the solder preform extends out of the opening.

3. The package of claim 1, wherein the solder preform is contained within the opening.

4. The package of claim 1, wherein the solder preform forms an electrical connection with only one electrically conductive layer comprised in the laminated substrate.

5. The package of claim 1, wherein the solder preform forms an electrical connection with at least two electrically conductive layers comprised in the laminated substrate.

6. The package of claim 1, wherein the solder preform is melted to effect the fixed coupling of the laminated substrate to the metal containing substrate.

7. A semiconductor package comprising:
a metal containing substrate comprising a metal projection; and
a laminated substrate comprising an opening;
wherein the laminated substrate is fixedly coupled to the metal containing substrate through an adhesive fixedly coupled between the metal projection extending through the opening and the laminated substrate.

8. The package of claim 7, wherein the metal projection is a pin and the metal containing substrate comprises a pin opening through which the pin extends.

9. The package of claim 8, wherein the pin is held in the pin opening using an adhesive.

10. The package of claim 8, wherein the pin is held in the pin opening using a jig.

11. The package of claim 7, wherein the metal projection is a portion of the metal containing substrate itself.

12. The package of claim 7, wherein the metal projection is a portion of the metal containing substrate that is bent upwardly substantially 90 degrees.

13. The package of claim 7, wherein the adhesive is cured using a laser beam.

14. A semiconductor package comprising:
a metal containing substrate comprising a horizontal section, the horizontal section comprising a first opening therein and a second opening thereon, the first opening and the second opening connected by a flow channel; and
a laminated substrate comprising a first largest planar surface
wherein the laminated substrate is fixedly coupled to the metal containing substrate at the first largest planar surface through an adhesive comprised in the second opening and in the flow channel.

15. The package of claim 14, wherein a base of the first opening is at a first distance into a thickness of the horizontal section and a base of the second opening is at a second distance into the thickness of the horizontal section.

16. The package of claim 15, wherein the first distance is smaller than the second distance.

17. The package of claim 14, wherein the flow channel permits gravity flow of the adhesive when melted by a laser beam from the first opening into the second opening.

18. The package of claim 14, wherein the flow channel is exposed on a same side of the horizontal section that comprises the first opening and the second opening.

19. The package of claim 14, wherein the flow channel is narrower than a width of the first opening and narrower than a width of the second opening.

20. The package of claim 14, wherein the flow channel is the same width as a width of the first opening and a width of the second opening.
